(19) United States
(12) Patent Application Publication
(10) Pub. No.: US 2026/0339397 A1
(43) Pub. Date: Oct. 29, 2026

(54) SUPPORT MEMBER AND FLEXIBLE DISPLAY DEVICE

(71) Applicant: BOE TECHNOLOGY GROUP CO., LTD., Beijing (CN)

(72) Inventors: Haoran WANG, Beijing (CN); Song ZHANG, Beijing (CN); Lu LIU, Beijing (CN); Xiaoming HAO, Beijing (CN); Zihan GAO, Beijing (CN)

(73) Assignee: BOE TECHNOLOGY GROUP CO., LTD., Beijing (CN)

(21) Appl. No.: 18/995,922

(22) PCT Filed: Apr. 17, 2024
(86) PCT No.: PCT/CN2024/088278

§ 371 Date: Jan. 17, 2025

(30) Foreign Application Priority Data
May 22, 2023 (CN) 202310580350.9

(51) Int. Cl. G06F 1/16; G09F 9/30; H10K 77/10

(52) U.S. Cl. CPC G06F 1/1656; G06F 1/1652; G09F 9/301; H10K 77/111

(57) ABSTRACT

Disclosed is a support member. The support member includes a support body, the support body having a planar region, at least one first bendable region, and at least one second bendable region. The at least one first bendable region and the at least one second bendable region are intersected to form at least one bidirectionally bendable region. The bidirectionally bendable region has a plurality of sawtooth-shaped connection wires arranged along an extension direction of the first bendable region. A region in the first bendable region other than the bidirectionally bendable region is a first unidirectionally bendable region. A region in the second bendable region other than the bidirectionally bendable region is a second unidirectionally bendable region. The planar region is a region on the support body other than the first bendable region and the second bendable region.

### CROSS REFERENCE TO RELATED APPLICATIONS

This application is a U.S. national phase application based on PCT/CN2024/088278, filed on Apr. 17, 2024, which claims priority to Chinese Patent Application No. 202310580350.9, filed on May 22, 2023, entitled “SUPPORT MEMBER AND FLEXIBLE DISPLAY DEVICE,” both of which are incorporated by reference herein.

### TECHNICAL FIELD

Embodiments of the present disclosure relate to the field of display technologies, and in particular, relate to a support member and a flexible display device.

### BACKGROUND

With the development of display technologies, display devices are more and more widely used, among which flexible display devices gain much concern. The flexible display devices are relatively thin and light, highly flexible and other characteristics, and realize different application forms such as folding and rolling.

### SUMMARY

Embodiments of the present disclosure provide a support member and a flexible display device that enables the support member to be foldable in two directions. The technical solutions are as follows:

In one aspect, a support member is provided. The support member includes a support body, having a planar region, at least one first bendable region, and at least one second bendable region; wherein the at least one first bendable region and the at least one second bendable region are intersected to form at least one bidirectionally bendable region, and the support body includes a plurality of connection wires disposed in the bidirectionally bendable region, wherein the plurality of connection wires are sawtooth-shaped and are arranged along a first direction and extend along a second direction, the first direction being an extension direction of the first bendable region and the second direction being an extension direction of the second bendable region direction; a region in the first bendable region other than the bidirectionally bendable region is a first unidirectionally bendable region, wherein a first opening pattern is disposed in the first unidirectionally bendable region; a region is the second bendable region other than the bidirectionally bendable region is a second unidirectionally bendable region, wherein a second opening pattern is disposed the second unidirectionally bendable region; and the planar region is a region on the support body other than the at least one first bendable region and the at least one second bendable region.

In some embodiments, each of the plurality of connection wires includes a plurality of sawtooth structures sequentially connected in the second direction, wherein each of the plurality of sawtooth structures satisfies:

$$\frac{{c}^{3}}{{A}^{3}} \times 1 {0}^{5} \leq 462$$

wherein C represents a line width of the each of the plurality of sawtooth structures, and A represents a maximum size of the each of the plurality of sawtooth structures in the first direction.

In some embodiments, a size of the each of the plurality of sawtooth structures ranges from 0.5 mm to 2 mm in the first direction, a line width of the each of the plurality of sawtooth structures ranges from 0.05 mm to 0.3 mm, and a size of an opening of the each of the plurality of sawtooth structures ranges from 0.05 mm to 1 mm.

In some embodiments, a spacing between two adjacent connection wires ranges from 0.1 mm to 2 mm.

In some embodiments, structures of the plurality of sawtooth structures are the same, and sizes of the plurality of sawtooth structures are the same.

In some embodiments, in the first direction, a spacing of two adjacent connection wires in the bidirectionally bendable region close to a center of the bidirectionally bendable region is greater than a spacing of two adjacent connection wires away from the center of the bidirectionally bendable region.

In some embodiments, on any one of the plurality of connection wires in the bidirectionally bendable region in the second direction, a size of a sawtooth structure close to a center of the bidirectionally bendable region in the first direction is greater than a size of a sawtooth structure away from the center of the bidirectionally bendable region in the first direction.

In some embodiments, the plurality of connection wires include a first connection wire and a second connection wire adjacent to each other, wherein the first connection wire and the second connection wire are symmetrically arranged about an axis of symmetry, wherein the axis of symmetry is between the first connection wire and the second connection wire, and a length direction of the axis of symmetry is the second direction.

In some embodiments, the support body further includes at least one third connection wire disposed in the bidirectionally bendable region, wherein the third connection wire extends in the first direction and is connected to at least two connection wires adjacent to each other in the first direction.

In some embodiments, a plurality of openings are defined in the third connection wire, wherein the openings are in an elongated shape, a circular shape, or a diamond shape.

In some embodiments, any one of the plurality of connection wires includes a plurality of first portions and a plurality of second portions alternately connected; a number of the sawtooth structures included in the first portion is less than a number of the sawtooth structures included in the second portion, and a size of each of the sawtooth structures in the first portion in the first direction is greater than a size of each of the sawtooth structures in the second portion in the first direction; and the plurality of the first portions of the plurality of connection wires are arrayed along the first direction and the second direction, and the plurality of the second portions of the plurality of connection wires are arrayed along the first direction and the second direction.

In some embodiments, the support body includes at least two bidirectionally bendable regions, wherein the at least two bidirectionally bendable regions are aligned in the first direction or in the second direction, and a spacing between the two adjacent bidirectionally bendable regions is greater than or equal to 2 mm.

In some embodiments, the first opening pattern includes a plurality of first openings that are arrayed, wherein a length direction of each of the plurality of first openings is the same as the first direction; and the second opening pattern includes a plurality of second openings that are arrayed, wherein a length direction of each of the plurality of the second openings is the same as the second direction.

In some embodiments, the first unidirectionally bendable region includes a first transition region, wherein the first transition region is disposed in a region of the first unidirectionally bendable region in the second direction close to the planar region; and the first transition region includes a plurality of third openings, wherein a length direction of each of the plurality of third openings is the first direction, a length of the each of the plurality of third openings is less than a length of the each of the plurality of first openings, and a length of a third opening in the plurality of third openings close to the planar region is less than a length of a third opening in the plurality of third openings away from the planar region.

In some embodiments, the second unidirectionally bendable region includes a second transition region, wherein the second transition region is disposed in a region of the second unidirectionally bendable region in the first direction close to the planar region; and the second transition region includes a plurality of fourth openings, wherein a length of each of the plurality of fourth openings is the second direction, a length of the each of the plurality of fourth openings is less than a length of the each of the plurality of second openings, and a length of a fourth opening in the plurality of fourth openings close to the planar region is less than a length of a fourth opening in the plurality of fourth openings away from the planar region.

In some embodiments, one or more rows of the second openings are defined between the two adjacent connection wires in the first direction.

In some embodiments, a thickness of the support body ranges from 0.05 mm to 0.3 mm.

In some embodiments, the support body is made of one of stainless steel, a titanium alloy, an aluminum alloy, a carbon fiber composite plate, and a glass fiber composite plate.

In some embodiments, the support member further includes a first bonding layer, a spacer layer and a second bonding layer, wherein the support body, the first bonding layer, the spacer layer, and the second bonding layer are sequentially stacked.

In some embodiments, a thickness of the first bonding layer ranges from 0.005 mm to 0.05 mm; a thickness of the second bonding layer ranges from 0.005 mm to 0.05 mm; and a thickness of the spacer layer ranges from 0.005 mm to 0.2 mm.

In some embodiments, the first bonding layer is made of an acrylic pressure-sensitive adhesive or an organosilicon pressure-sensitive adhesive; and the second bonding layer is made of an acrylic pressure-sensitive adhesive or an organosilicon pressure-sensitive adhesive.

In some embodiments, the spacer layer is made of one of stainless steel, copper, polyimide, polyethylene terephthalate, an acrylic-modified foam, a polyurethane-modified foam, or a silicone-modified foam.

In another aspect, a flexible display device is provided. The flexible display device includes: a flexible display panel, a third bonding layer, a cover plate, and any one of the support members mentioned above. The support member, the flexible display panel, the third bonding layer, and the cover plate are sequentially stacked.

The technical solutions according to the embodiments of the present disclosure achieve the following beneficial effects:

The bidirectionally bendable region enables bending in both directions. By arranging a plurality of connection wires that are sawtooth-shaped in the bidirectionally bendable region, a support member foldable in both directions is obtained.

### BRIEF DESCRIPTION OF DRAWINGS

For clearer descriptions of the technical solutions in the embodiments of the present disclosure, the following briefly introduces the accompanying drawings required for describing the embodiments. Apparently, the accompanying drawings in the following description illustrate merely some embodiments of the present disclosure, and persons of ordinary skill in the art may still derive other drawings from these accompanying drawings without creative efforts.

FIG. 1 is a schematic structural diagram of a support body according to some embodiments of the present disclosure;

FIG. 2 is a schematic structural diagram of another support body according to some embodiments of the present disclosure;

FIG. 3 is a schematic structural diagram of another support body according to some embodiments of the present disclosure;

FIG. 4 is a schematic structural diagram of a bidirectionally bendable region according to some embodiments of the present disclosure;

FIG. 5 is a schematic structural diagram of another bidirectionally bendable region according to some embodiments of the present disclosure;

FIG. 6 is a schematic structural diagram of another bidirectionally bendable region according to some embodiments of the present disclosure;

FIG. 7 is a schematic structural diagram of another bidirectionally bendable region according to some embodiments of the present disclosure;

FIG. 8 is a schematic structural diagram of another support body according to some embodiments of the present disclosure;

FIG. 9 is a partially enlarged view of FIG. 8;

FIG. 10 is a schematic structural diagram of another support body according to some embodiments of the present disclosure;

FIG. 11 is a partially enlarged view of FIG. 10;

FIG. 12 is a schematic diagram of the structure of another support body according to some embodiments of the present disclosure;

FIG. 13 is a partially enlarged view of FIG. 12;

FIG. 14 is a schematic structural diagram of another support body according to some embodiments of the present disclosure;

FIG. 15 is a schematic structural diagram of another support body according to some embodiments of the present disclosure;

FIG. 16 is a schematic structural diagram of another support body according to some embodiments of the present disclosure;

FIG. 17 is a schematic cross-sectional structural diagram of a support member according to some embodiments of the present disclosure; and

FIG. 18 is a schematic cross-sectional structural diagram of a flexible display device according to some embodiments of the present disclosure.

### REFERENCE NUMERALS

1-support member, 2-flexible display panel, 3-third bonding layer, 4-cover plate, 10-support body, 20-first bonding layer, 30-spacer layer, 40-second bonding layer, x-first direction, y-second direction, m-first bending axis, n-second bending axis, 13-planar region, 11-first bendable region, 111-first transition region, 110-first unidirectionally bendable region, 1101-first opening, 1102-third opening, 12-second Bendable region, 121-second transition region, 120-second unidirectionally bendable region, 1201-second opening, 1202-fourth opening, 100-bidirectionally bendable region, 101-connection wire, 106-sawtooth structure, 102-first connection segment, 103-second connection segment, 104-third connection segment, 105-fourth connection segment, 10101-first portion, 10102-second portion, 1011-first connection wire, 1012-second connection wire, 1013-third connection wire, 10130-opening of third connection wire.

### DETAILED DESCRIPTION

In order to make the purpose, technical solutions, and advantages of the present disclosure clearer, the embodiments of the present disclosure are described in further detail below in conjunction with the accompanying drawings.

Unless otherwise defined, technical or scientific terms used herein shall have their ordinary meaning as understood by a person of ordinary skill in the art to which the present disclosure pertains. The terms “first,” “second,” “third,” and the like, as used in the specification and claims of the patent disclosure, do not denote any order, number, or importance, but are used only to distinguish the different components. Similarly, the words “a” or “an” and similar terms do not indicate a limitation of quantity, but rather the existence of at least one. Terms like “includes” or “comprises” and other similar terms mean that the elements or objects now preceding “includes” or “comprises” encompass the elements or objects listed after “includes” or “comprises” and their equivalents, and do not exclude other elements or objects. The terms such as “connect” or “connected” are not limited to physical or mechanical connections, but may include electrical connections, whether direct or indirect. The terms “up,” “down,” “left,” “right,” “top,” “bottom,” and the like are used to indicate relative positional relationships only, and when the absolute position of the object being described is changed, then the relative positional relationships may be changed accordingly.

In a flexible display device, a support member is disposed at the back of the flexible display panel. The support member includes stacked intermediate layers and a support body. The support body is bendable in both directions, and the intermediate layer is configured to connect the support body and the flexible display panel. While enhancing the overall support, tensile strength, and impact resistance of the flexible display device, the support member enables the flexible display device to be bendable in multiple directions.

Currently, a flexible display device typically includes a stacked support member and a flexible display panel. The support member includes a support body, wherein the support body has a planar region, at least one first bendable region, and at least one second bendable region. The at least one first bendable region and the at least one second bendable region are intersected to form at least one bidirectionally bendable region. The planar region is a region on the support body other than the at least one first bendable region and the at least one second bendable region. A region in the first bendable region other than the bidirectionally bendable region is a first unidirectionally bendable region, wherein the first unidirectionally bendable region has a first opening pattern. A region in the second bendable region other than the bidirectionally bendable region is a second unidirectionally bendable region, wherein the second unidirectionally bendable region has a second opening pattern. The bidirectionally bendable region has a plurality of opening regions.

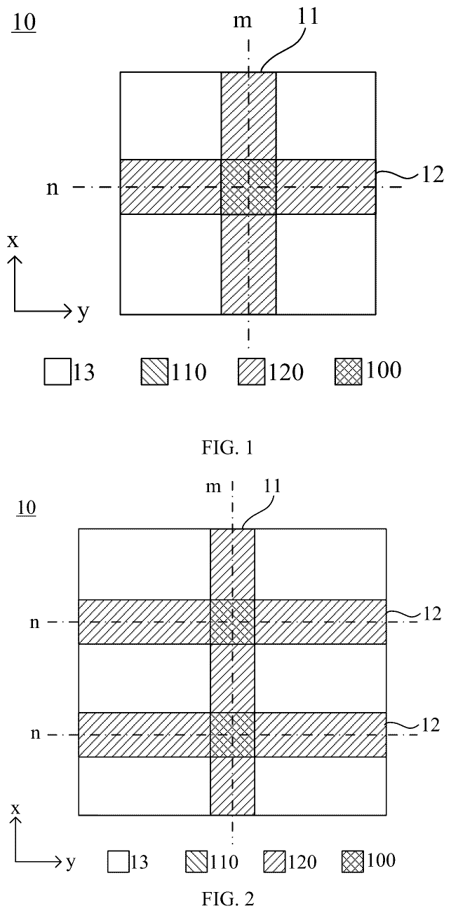

FIG. 1 is a schematic structural diagram of a support body according to some embodiments of the present disclosure. As shown in FIG. 1, the support body 10 has a planar region 13, at least one first bendable region 11, and at least one second bendable region 12. The at least one first bendable region 11 and the at least one second bendable region 12 are intersected to form at least one bidirectionally bendable region 100. The planar region 13 is a region on the support body 10 other than the at least one first bendable region 11 and the at least one second bendable region 12. As shown in FIG. 1, the support body 10 includes one first bendable region 11 and one second bendable region 12. The first bendable region 11 and the second bendable region 12 are intersected to form one bidirectionally bendable region 100.

FIG. 2 is a schematic structural diagram of another support body according to some embodiments of the present disclosure. As shown in FIG. 2, the support body 10 includes two bidirectionally bendable regions 100. The two bidirectionally bendable regions 100 are arranged along a first direction x.

In some embodiments, a plurality of bidirectionally bendable regions 100 may also be arranged along a second direction y. The bidirectionally bendable regions 100 can disposed along both the first direction x and the second direction y, such that more folding and carrying configurations are implemented.

It is noted that the support body 10 may also include the plurality of bidirectionally bendable regions 100, wherein a portion of the bidirectionally bendable regions 100 are arranged along a first direction x, and another portion of the bidirectionally bendable regions 100 are arranged along a second direction y. For example, the support body 10 includes two first bendable regions 11 and two second bendable regions 12. The two first bendable regions 11 and the two second bendable regions 12 are intersected to form four bidirectionally bendable regions 100. The four bidirectionally bendable regions 100 are arranged in an array.

In some embodiments, in the case that the support body 10 includes the plurality of bidirectionally bendable regions 100, a spacing between two adjacent bidirectionally bendable regions 100 is greater than or equal to 2 mm. The two adjacent bidirectionally bendable regions 100 are a first target bidirectionally bendable region 100 and a second target bidirectionally bendable region 100, respectively. In the case that a spacing of the first target bidirectionally bendable region 100 and the second target bidirectionally bendable region 100 is less than 2 mm, a spacing between a second unidirectionally bendable region 120 connected to the first target bidirectionally bendable region 100 and a second unidirectionally bendable region 120 connected to the second target bidirectionally bendable region 100 is less. The bending stress of one of the second unidirectionally bendable regions 120 at a second bending axis passing through the second unidirectionally bendable region 120 extends through a display film layer (e.g., a flexible display panel) having a whole-layer structure on the support member 1 to an adjacent region, such as the other second unidirectionally bendable region 120. As a result, the bending stress of the other second unidirectionally bendable region 120 at the second bending axis passing through the one second unidirectionally bendable region 120 is increased. The first target bidirectionally bendable region 100 and the second target bidirectionally bendable region 100 are connected by one first unidirectionally bendable region 110. Compared to a planar region 13, the first unidirectionally bendable region 110 is relatively soft and slightly deformed in the bending deformation, which is more likely to result in the bending stresses of the first target bidirectionally bendable region 100 and the second target bidirectionally bendable region 100 affecting each other.

The following is an example of a support body 10 including one first bendable region 11 and one second bendable region 12.

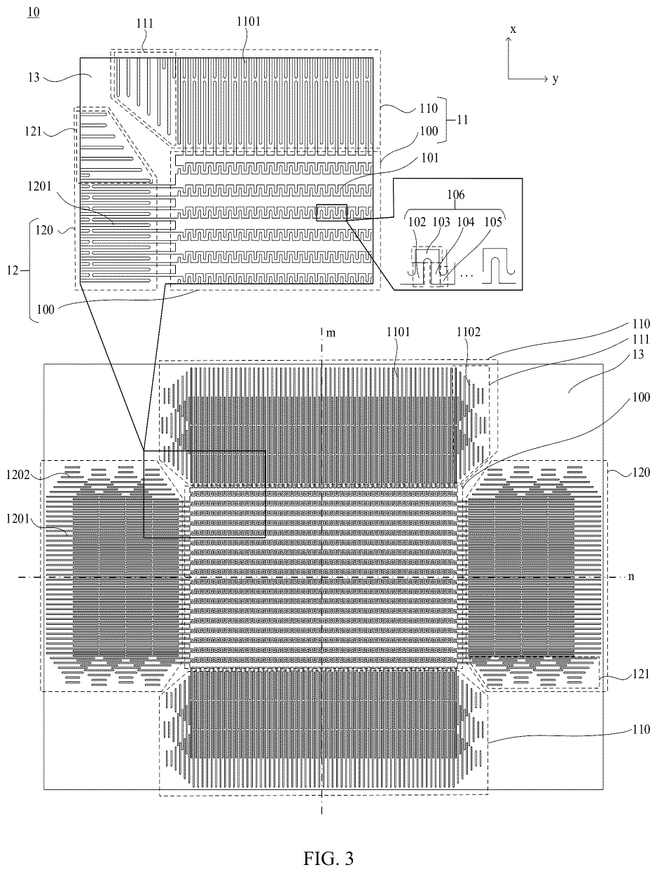

FIG. 3 is a schematic structural diagram of another support body according to some embodiments of the present disclosure. As shown in FIG. 3, a region in the first bendable region 11 other than a bidirectionally bendable region 100 is a first unidirectionally bendable region 110. A first opening pattern is disposed in the first unidirectionally bendable region 110. The region in the second bendable region 12 other than the bidirectionally bendable region 100 is a second unidirectionally bendable region 120. A second opening pattern is disposed in the second unidirectionally bendable region 120.

For the first bendable region 11, the second bendable region 12, and the bidirectionally bendable region 100 formed by the intersection of the first bendable region 11 and the second bendable region 12, the support body 10 has a first bending axis m and a second bending axis n, the first bending axis being parallel to a first direction x, and the second bending axis being parallel to a second direction y. The first bending axis m and the second bending axis n refer to imaginary axial lines rather than actual physical axes. The support body 10 may bend in the second direction y and the first direction x along the first bending axis and the second bending axis, respectively. The first bending axis and the second bending axis both pass through a center of the first bending region 11, and the second bending axis is disposed between two connection wires 101 and does not pass through the connection wires 101.

As shown in FIG. 3, in the embodiments of the present disclosure, the support body 10 includes a plurality of sawtooth connection wires 101 in the bidirectionally bendable region 100. The plurality of connection wires 101 are arranged in a first direction x. An extension direction of the connection wires 101 and an extension direction of the second bendable region 12 (hereinafter referred to as the second direction y) are the same. The first direction x is an extension direction of the first bendable region 11.

As the first bendable region 11 and the second bendable region 12 are intersected to form the bidirectionally bendable region, the first direction x is intersected with the second direction y. Exemplarily, the first direction x is perpendicular to the second direction y. In other embodiments, the first direction x and the second direction y may also be at an angle other than 90 degrees.

The connection wire 101 in the embodiments includes a plurality of sawtooth structures 106 sequentially connected in the second direction y. Each sawtooth structure 106 includes at least one connection segment.

As shown in FIG. 3, each sawtooth structure 106 includes a plurality of connection segments sequentially connected: a first connection segment 102, a second connection segment 103, a third connection segment 104, and a fourth connection segment 105. A length direction of each of the first connection segment 102 and the third connection segment 104 is parallel to the first direction x, and a length direction of each of the second connection segment 103 and the fourth connection segment 105 is parallel to the second direction y.

Exemplarily, as shown in FIG. 3, the first connection segment 102 has two linear sides arranged along the second direction y. The third connection segment 104 has two linear sides arranged along the second direction y. The second connection segment 103 has a linear side and an arcuate shaped side arranged along the first direction x. The fourth connection segment 105 has an arcuate shaped side and a linear side arranged along the first direction x. In the four sides, the linear side of the second connection segment 103 and the arcuate side of the fourth connection segment 105 are close to a terminal end of the first direction x, while the arcuate side of the second connection segment 103 and the linear side of the fourth connection segment 105 are close to a starting end of the first direction x. Compared to a linear connection, the arcuate shaped side of the second connection segment 103 and the arcuate shaped side of the fourth connection segment 105, which are connected in an arcuate shaped manner, can evenly release the stress during bending.

In the example, the first bending axis m passes through the second connection segment 103 or the fourth connection segment 105 of the sawtooth structure 106 disposed in the middle of the connection wire 101 in the second direction y.

In other possible embodiments, each sawtooth structure 106 includes a plurality of connection segments sequentially connected: a first connection segment 102, a second connection segment 103, a third connection segment 104, and a fourth connection segment 105. The first connection segment 102 and the third connection segment 104 are identical to the structure shown in FIG. 3, wherein each of the segments has two linear sides arranged in the second direction y. The second connection segment 103 and the fourth connection segment 105 are different from the structure shown in FIG. 3. The second connection segment 103 has two linear sides arranged in the first direction x, and the fourth connection segment 105 has two linear sides arranged in the first direction x.

Exemplarily, referring to FIG. 3 again, the first opening pattern includes a plurality of elongated first openings 1101 that are arrayed, and a length direction of each first opening 1101 is the same as the first direction x. In the case that the support body 10 is bent in the second direction y (i.e., bent along the first bending axis m), the plurality of first openings 1101 effectively reduces the bending stress, thereby facilitating the bending of the support body and avoiding fracture of the support body during bending.

In some embodiments, the first opening 1101 is shaped as a rectangle, an oval, or a waisted circle. In some examples, different first openings 1101 may have the same or different lengths.

Exemplarily, the second opening pattern includes a plurality of elongated second openings 1201 that are arrayed. A length direction of the first second openings 1201 is the same as the second direction y. Similarly, in the case that the support body 10 is bent in the first direction x (i.e., bent along the second bending axis n), the plurality of second openings 1201 effectively reduces the bending stress, thereby facilitating the bending of the support body and avoiding fracture of the support body during bending.

In some embodiments, the second opening 1201 is shaped as a rectangle, an oval, or a waisted circle. In some examples, different second openings 1201 may have the same or different lengths.

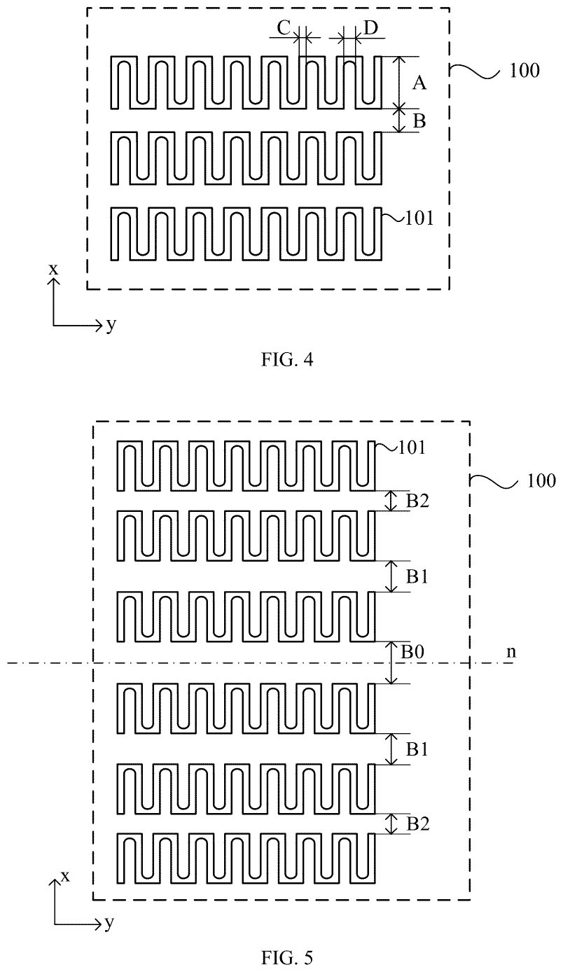

FIG. 4 is a schematic structural diagram of a bidirectionally bendable region according to some embodiments of the present disclosure. As shown in FIG. 4, a sawtooth structure 106 of a connection wire 101 satisfies:

$$α = \frac{{c}^{3}}{{A}^{3}} \times 1 {0}^{5} \leq 462$$

wherein α represents a structural parameter of the sawtooth structure, which has no practical significance, and is obtained by calculating based on line width and the maximum size of the sawtooth structure in the first direction x; C represents the line width of the sawtooth structure, i.e., a width of each connection segment of the sawtooth structure in a direction perpendicular to an extension direction of each connection segment, e.g., a width of a first connection segment 102 in a direction perpendicular to an extension direction of the first connection segment 102; and A represents a maximum size of the sawtooth structure in the first direction x, i.e., a length of the first connection segment 102 and a third connection segment 104 in the first direction x as described above. The length units of A and C in the formula are both in millimeters (mm). The connection wire 101 whose sizes conform to the configuration is experimentally verified that no new defect and no cracking and destruction of the support member 1 are caused after the support member 1 is dynamically bent along the first bending axis and the second bending axis for two hundred thousand times, and thus the folding reliability of the support member 1 is good and conforms to the product requirements, α>462 leads to fracture of the support body during bending. Some validation results are shown in Table 1.

TABLE 1
Verification results of the structural
parameter a of the connection wire

| A/mm | C/mm | α = C\hat{ }3*10\hat{ }5/A\hat{ }3 | Folding Reliability |
|---|---|---|---|
| 1.2 | 0.08 | 29.62962963 | OK |
| 1.2 | 0.1 | 57.87037037 | OK |
| 1.2 | 0.12 | 100 | OK |
| 1.2 | 0.15 | 195.3125 | OK |
| 1.2 | 0.2 | 462.962963 | NG |

Exemplarily, the sawtooth structure 106 satisfies the following conditions: A ranges from 0.5 mm to 2 mm, C ranges from 0.05 mm to 0.3 mm, and D ranges from 0.05 mm to 1 mm. For example, A is 0.5 mm, 1 mm, 1.2 mm, 1.5 mm, or 2 mm; B is 0.1 mm, 0.3 mm, 0.5 mm, 0.7 mm, 1 mm, 1.2 mm, 1.4 mm, 1.5 mm, 1.6 mm, 1.8 mm, or 2 mm; C is 0.05 mm, 0.08 mm, 0.1 mm, 0.12 mm, 0.15 mm, 0.2 mm, and 1.5 mm, 1.6 mm, 1.8 mm, or 2 mm, and Dis 0.05 mm, 0.08 mm, 0.1 mm, 0.2 mm, 0.3 mm, 0.4 mm, 0.5 mm, 0.6 mm, 0.7 mm, 0.8 mm, 0.9 mm, or 1 mm.

D represents the size of an opening of the sawtooth structure. This ensures that when the bidirectionally bendable region 100 is bent, the bidirectionally bendable region 100 does not fracture, and the support member 1 has a good bending capacity and a strong ability to return to flatness after bending.

The size of the opening refers to a spacing between two adjacent teeth in one sawtooth structure 106. For example, referring to FIG. 3, the size of the opening is a size of an unenclosed region formed by the first connection segment 102, the second connection segment 103, and the third connection segment 104 sequentially connected in the second direction y, or the size of the opening is a size of an unenclosed region formed by the third connection segment 104, the fourth connection segment 105 in the first sawtooth structure, and the first connection segment in the second sawtooth structure 102 sequentially connected. The first sawtooth structure and the second sawtooth structure are adjacent to each other, and the fourth connection segment 105 of the first sawtooth structure is connected to the first connection segment 102 of the second sawtooth structure.

In one possible implementation, as shown in FIG. 4, a plurality of sawtooth structures on one connection wire 101 have the same structure and size. The same structure and size herein means that one sawtooth structure may be obtained by translating another sawtooth structure along the second direction y.

Exemplarily, as shown in FIG. 4, a spacing between any two adjacent connection wires 101 in the bidirectionally bendable region 100 is equal in the first direction x.

For example, in conjunction with FIGS. 3 and 4, the spacing between any two adjacent connection wires 101 in the first direction x may be equal to an integer multiple of a spacing (a spacing between center lines of the two second openings 1201) between two adjacent second openings 1201 in the first direction x, such as a multiple of 1, a multiple of 2, or a multiple of 3. That is, one or more rows of second openings 1201 are defined between two adjacent connection wires 101 in the first direction x.

In some embodiments, the spacing B between two adjacent connection wires 101 ranges from 0.1 mm to 2 mm.

FIG. 5 is a schematic structural diagram of another bidirectionally bendable region according to some embodiments of the present disclosure. As shown in FIG. 5, in the bidirectionally bendable region 100 in a first direction x, a spacing between two adjacent connection wires 101 close to a center of the bidirectionally bendable region 100 is greater than a spacing between two adjacent connection wires 101 away from the center of the bidirectionally bendable region 100. In the first direction x, the center of the bidirectionally bendable region 100 is a second bending axis n.

For example, B0 is a spacing between the two adjacent connection wires 101 closest to the second bending axis n, i.e., a spacing between a first one of the connection wires 101 above the second bending axis n and a first one of the connection wires 101 under the second bending axis n. B1 represents a spacing between a first one of the connection wires 101 and a second one of the connection wires 101 above the second bending axis n, or represents a spacing between a first one of the connection wires 101 and a second one of the connection wires 101 under the second bending axis n. The two connection wires 101 corresponding to B1 are farther away from the second bending axis n relative to the two connection wires 101 corresponding to B0. B2 represents a spacing between a second one of connection wires 101 and a third one of the connection wires 101 above the second bending axis n, or a spacing between a second one of the connection wires 101 and a third one of the connection wires 101 under the second bending axis n. The two connection wires 101 corresponding to B2 are farther away from the second bending axis n relative to the two connection wires 101 corresponding to B1. B0 is greater than B1, and B1 is greater than B2.

The closer to the second bending axis n, the greater the bending stress, the greater spacing is defined between adjacent connection lines, so as to facilitate the release of stress.

In the embodiments of the present disclosure, the bidirectionally bendable region 100 is connected to the unidirectionally bendable regions on both sides of the first direction x or of the second direction y by the connection wire 101.

In one possible implementation, the spacing between two adjacent connection wires 101 is an integer multiple of the spacing between two adjacent second openings 1201 in the second unidirectionally bendable region 120 corresponding to the two adjacent connection wires 101 (the spacing between the center lines of the two second openings 1021), such as a multiple of 1, a multiple of 2, or a multiple of 3. For example, the term “corresponding” refers to a relationship between the second openings 1201 and the connection wires 101 that satisfies the following condition: a projection of one or more second openings 1201 in the second unidirectionally bendable region 120 in the first direction x (i.e., a projection of one or more second openings 1201 in the first bending axis m) is within a gap between the corresponding two adjacent connection wires 101.

For example, in the first direction x, in the bidirectionally bendable region 100, a spacing between two adjacent connection wires 101 close to the center of the bidirectionally bendable region 100 is p1 times the spacing of the two aforementioned second openings 1201, and a spacing between two adjacent connection wires 101 away from the center of the bidirectionally bendable region 100 is p2 times the spacing between the two aforementioned second openings 1201. Both p1 and p2 are positive integers and p1 is greater than p2.

In the embodiments of the present disclosure, the second bending axis n running through the second unidirectionally bendable region 120 runs through the second opening 1201. That is, the second bending axis n runs through a region with the least solid portion of the second unidirectionally bendable region 120. At the same time, the second bending axis n running through the bidirectionally bendable region 100 runs through the gap between two adjacent connection wires 101. That is, the second bending axis n runs through a region with the least solid portion of the bidirectionally bendable region 100, such that it is more favorable for the bidirectionally bendable region 100 to bend.

FIG. 6 is a schematic structural diagram of another bidirectionally bendable region according to some embodiments of the present disclosure. As shown in FIG. 6, on any connection wire 101 in the bidirectionally bendable region 100, in a second direction y, a size A1 of a sawtooth structure close to a center of the bidirectionally bendable region 100 in a first direction is greater than a size A2 of a sawtooth structure away from the center of the bidirectionally bendable region 100 in the first direction. In the second direction y, the center of the bidirectionally bendable region 100 is disposed at a position of a first bending axis. The closer to the first bending axis, the greater the bending stress, and thus a greater size of the sawtooth structure in the first direction x facilitates the release of the stress. In this case, in the second direction y, from one end to the other end of one connection wire 101, the size A of the sawtooth structure increases and then decreases, which is also referred to as a change period of the size A. One connection wire 101 may have only one change period of the size A.

In another possible implementation, one connection wire 101 may have a plurality of change periods of the size A. For example, two change periods of the size A are provided, i.e., from one end to the other end of one connection wire 101, the size A of the sawtooth structure in the first direction may increase and then decrease, and increase, and finally decrease. For another example, three change periods of size A are provided. For example, from one end to the other end of one connection wire 101, the size A of the sawtooth structure in the first direction may increase and then decrease, increase and then decrease, and increase and finally decrease.

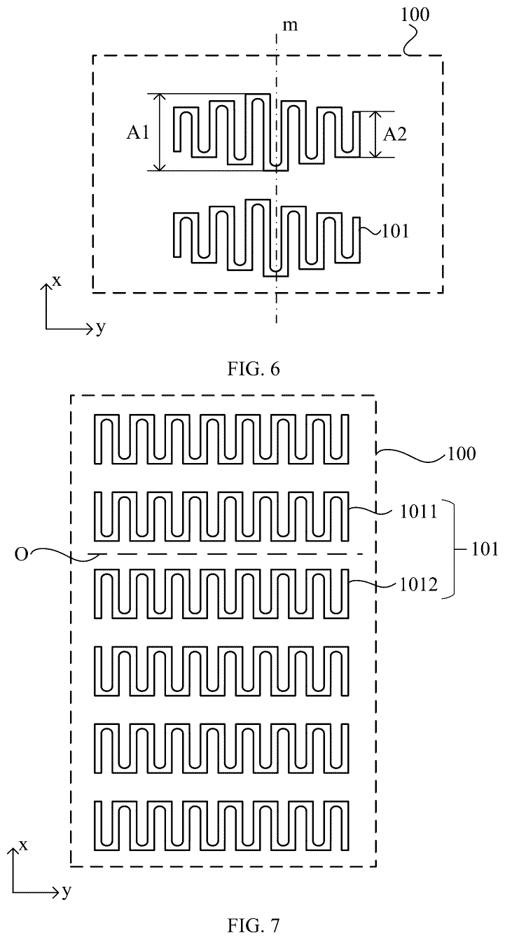

FIG. 7 is a schematic structural diagram of another bidirectionally bendable region according to some embodiments of the present disclosure. As shown in FIG. 7, a plurality of connection wires 101 includes a first connection wire 1011 and a second connection wire 1012 adjacent to each other. The first connection wire 1011 and the second connection wire 1012 are symmetrically arranged with respect to an axis of symmetry O. The axis of symmetry O is present between the first connection wire 1011 and the second connection wire 1012, and a length direction of the axis of symmetry O is a second direction y.

In the embodiment shown in FIG. 7, the first connection wire 1011 and the second connection wire 1012 have a plurality of opening regions in a first direction x, respectively. The plurality of opening regions of the first connection wire 1011 close to the second connection wire 1012 are in one-to-one correspondence with the plurality of opening regions of the second connection wire 1012 close to the first connection wire 1011. In conjunction with FIG. 3, the opening region refers to the unenclosed region in one sawtooth structure 106 formed by the first connection segment 102, the second connection segment 103, and the third connection segment 104 sequentially connected. That is, the second connection wire 1012 has an offset of a half period in a second direction y relative to the first connection wire 1011. One period is one sawtooth structure.

In another possible implementation, the second connection wire 1012 has an offset of one-quarter period in the second direction y relative to the first connection wire 1011.

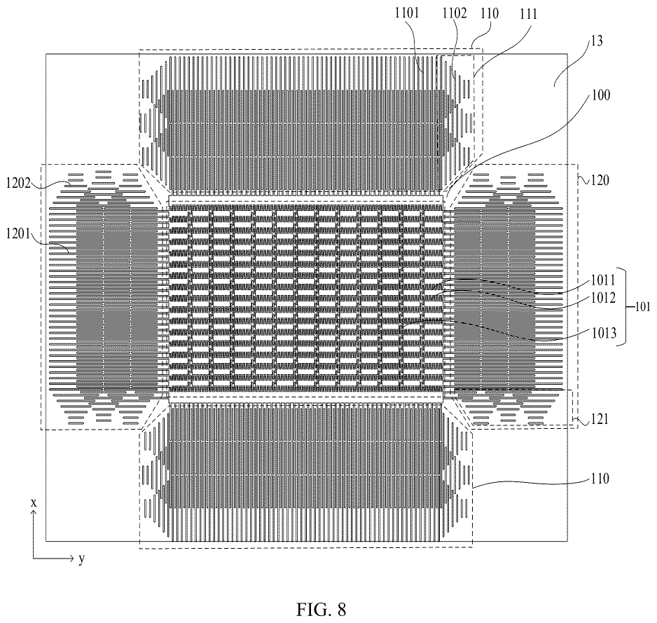

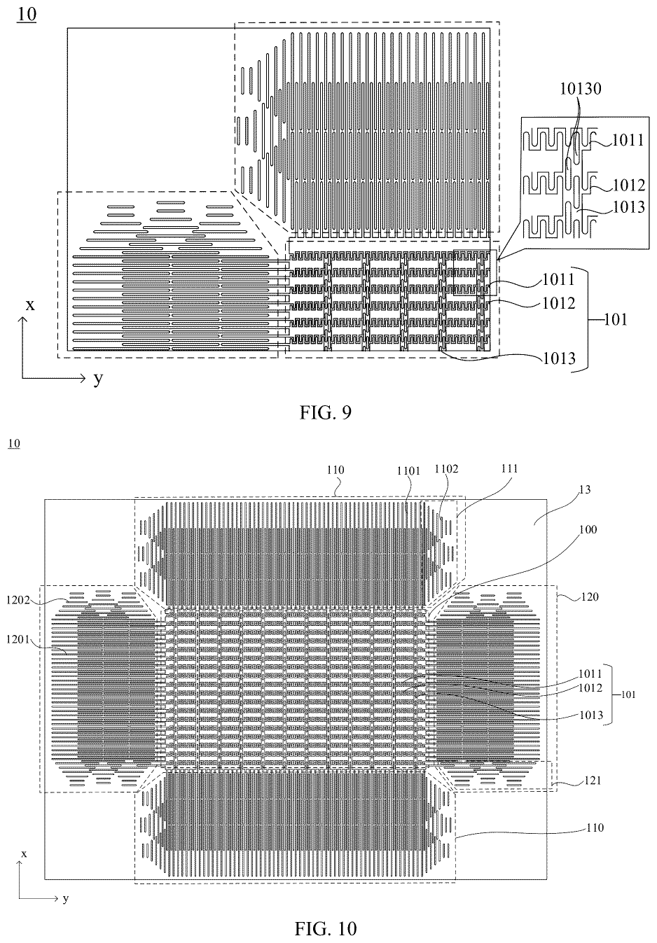

FIG. 8 is a schematic structural diagram of another support body according to some embodiments of the present disclosure. FIG. 9 is a partially enlarged view of FIG. 8. As shown in FIGS. 8 and 9, the bidirectionally bendable region 100 further includes at least one third connection wire 1013 in the bidirectionally bendable region 100. The third connection wire 1013 extends along a first direction x, and is connected to a plurality of connection wires 101 adjacent to each other in the first direction.

In one possible implementation, a plurality of elongated openings 10130 are defined in the third connection wire 1013, and a length direction of the openings is the first direction x. In some embodiments, the elongated opening 10130 may be rectangular, spindle, oval, or the like. In another possible implementation, the opening 10130 may be square, rhombus, circular, or the like, which is not limited in the embodiments of the present disclosure.

In some embodiments, as shown in FIG. 9, the third connection wire 1013 is connected to all connection wires 101 adjacent to each other in the first direction x.

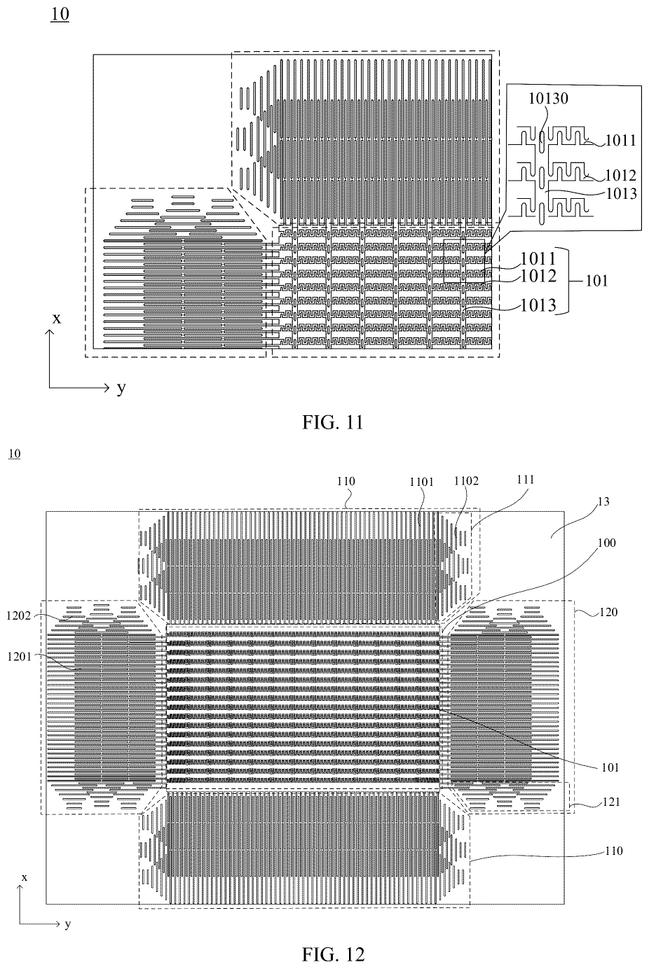

Exemplarily, the plurality of openings 10130 in the third connection wire 1013 are divided into a plurality of rows in the second direction y. As shown in FIGS. 8 and 9, the plurality of openings 10130 in the third connection wire 1013 are divided into two rows in the second direction y. As shown in FIGS. 10 and 11, the plurality of openings 10130 in the third connection wire 1013 may also be in only one row in the second direction y. FIG. 10 is a schematic structural diagram of another support body according to some embodiments of the present disclosure. FIG. 11 is a partially enlarged view of FIG. 10.

FIG. 12 is a schematic structural diagram of another support body according to some embodiments of the present disclosure. FIG. 13 is a partially enlarged view of FIG. 12. As shown in FIGS. 12 and 13, any one of a plurality of connection wires 101 includes a plurality of first portions 10101 and a plurality of second portions 10102 that are alternately connected. The number of sawtooth structures included in each of the first portions 10101 is less than the number of sawtooth structures included in each of the second portions 10102. The size of each of the sawtooth structures in the first portion 10101 in the first direction x is greater than a size of each of the sawtooth structures in the second portion 10102 in the first direction x.

Exemplarily, as shown in FIG. 13, the first portion 10101 includes two sawtooth structures and the second portion 10102 includes four sawtooth structures. In other possible embodiments, the first portion 10101 includes two sawtooth structures and the second portion 10102 includes five sawtooth structures, or the first portion 10101 includes three sawtooth structures and the second portion 10102 includes six sawtooth structures, or the like.

In other possible embodiments, the size of each of the sawtooth structures in the first portion 10101 in the first direction x is less than the size of each of the sawtooth structures in the second portion 10102 in the first direction x.

Exemplarily, the maximum size of each of the sawtooth structures in the first portion 10101 in the first direction x is 1.8 mm, and the maximum size of each of the sawtooth structures in the second portion 10102 in the first direction x is 1.6 mm. Alternatively, the maximum size of each of the sawtooth structures in the first portion 10101 in the first direction x is 1.9 mm, and the maximum size of each of the sawtooth structures in the second portion 10102 in the first direction x is 1.5 mm.

In actual processing and molding, as the plurality of connection wires arranged along the first direction x are long, the third connection wire (e.g., the embodiment shown in FIGS. 8 and 9) is provided in order to align the plurality of connection wires arranged along the first direction x. With this configuration, in order to further improve the bendability of the bidirectionally bendable region 100, a portion of the third connection wire 1013 between any two adjacent connection wires 101 is removed to obtain the support body shown in FIG. 3. However, in this process, localized shapes may be caused by process deviation, such that the support body shown in FIGS. 12 and 13 is obtained.

Exemplarily, as shown in FIGS. 12 and 13, the plurality of first portions 10101 of the plurality of connection wires 101 are arrayed along the first direction x and the second direction y. The plurality of second portions 10102 of the plurality of connection wires 101 are arrayed along the first direction x and the second direction y. It is experimentally verified that the bidirectionally bendable region 100 with localized shapes can also pass the bending test, thereby indicating that the localized shaped deviation has less effect on the folding reliability of the bidirectionally bendable region 100.

In one possible implementation, the support body shown in FIGS. 12 and 13 can be formed by a further processing of the support body shown in FIGS. 8 and 9. For example, in the support body 10 shown in FIGS. 8 and 9, a partial region of the third connection wire 1013 between the first connection wire 1011 and the second connection wire 1012 is removed by a laser cutting.

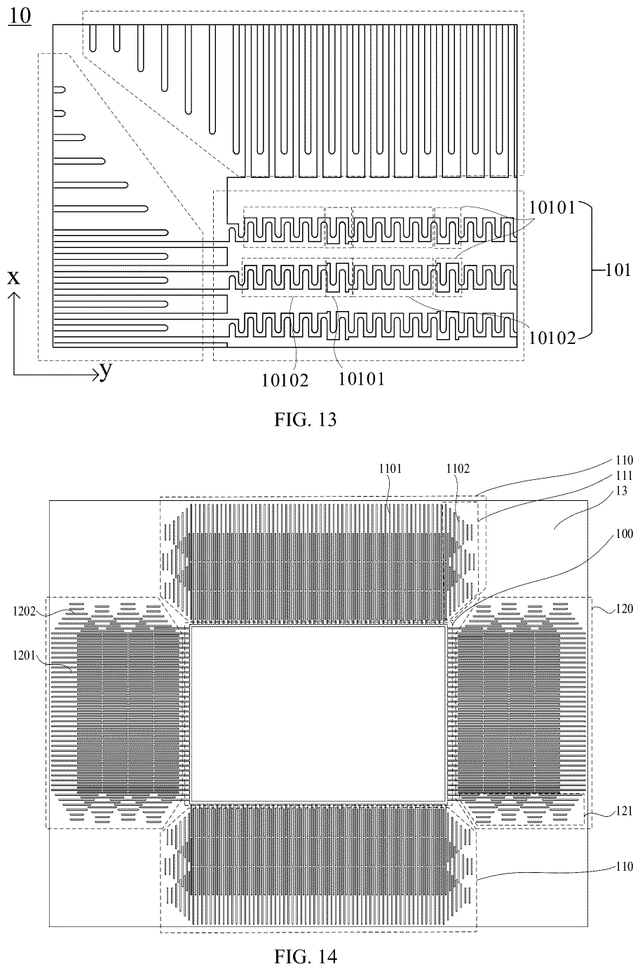

FIG. 14 is a schematic structural diagram of another support body according to some embodiments of the present disclosure. As shown in FIG. 14, in one possible implementation, the bidirectionally bendable region 100 does not include a plurality of connection wires 101, and is instead filled entirely with the elastic material.

In another possible implementation, the bidirectionally bendable region 100 does not include the plurality of connection wires 101, but is partially filled with the elastic material. The partially filled means that an initial support body 10 disposed in the bidirectionally bendable region 100 is a whole layer structure with no openings. A plurality of opening patterns are fabricated in the initial support body 10 of the bidirectionally bendable region 100, wherein the opening patterns include but are not limited to, circular holes, cross-shaped holes, square holes, and the like, and then the openings are filled with the elastic material.

The elastic material achieves a cushioning effect when the bidirectionally bendable region 100 is bent, which is conducive to reducing damage such as cracking of the bidirectionally bendable region 100 of the support body during bending. In some embodiments, the elastic material is made of at least one of polyurethane (PU), thermoplastic polyurethane (TPU), polyacrylate, rubber, or silicone rubber. The elastic material made of PU is also referred to as PU foam.

In some embodiments, a thickness t1 of the filled elastic material is the same or similar to a thickness t0 of the support body 10. Preferably, the difference in thickness between t1 and t0, e.g., Δt is equal to t1 minus t0, should be less than or equal to ±0.05 mm. In the case that the thickness of the material in a filled region is less than +0.05 mm than the thickness of the support body 10, serious depression is caused in the filled region. In the case that the thickness of the material in the filled region is greater than +0.05 mm than the thickness of the support body 10, a significant protrusion is formed in the filled region. As a result, both of the two situations are unfavorable to the flatness of the support member 1, and consequently, the flatness of other structures (e.g., a flexible display panel) disposed on the support member 1 is affected, and hence the display function of the flexible display device is affected.

In another possible implementation, the bidirectionally bendable region 100 has no solid structure.

In another possible implementation, the sawtooth structure 106 is formed by the first connection segment and the second connection segment which are connected. The first connection segment is arcuate, and the first connection segment includes two arcuate sides arranged along the first direction x, wherein the two arcuate sides protrude toward one side of the first direction x. The second connection segment is also arcuate, and the second connection segment includes two arcuate sides arranged along the first direction x, wherein the two arcuate sides protrude toward the other side of the first direction x. None of the above-mentioned sides are arranged between two adjacent connection segments. The connection wire 101 formed by the above-described sawtooth structures is wavy.

In another possible implementation, the sawtooth structure 106 is formed by the first connection segment and the second connection segment which are connected. The first connection segment includes two linear sides disposed relatively parallel to each other, the two linear sides are angled to both the first direction x and the second direction y. The second connection segment includes two linear sides disposed relatively parallel to each other, wherein the two linear sides are angled to both the first direction x and the second direction y. None of the above-mentioned sides are arranged between two adjacent connection segments. The connection wire 101 formed by the above-described sawtooth structures is a continuous triangular zigzag shape.

In one possible implementation, as shown in FIG. 3, the first unidirectionally bendable region 110 includes a first transition region 111. The first transition region 111 is disposed in a region of the first unidirectionally bendable region 110 close to a planar region 13 in the second direction y. The first transition region 111 includes a plurality of third openings 1102. A length direction of the plurality of third openings 1102 is the first direction x. A length of each of the plurality of third openings 1102 is less than a length of each of the plurality of first openings 1101. Among the plurality of third openings 1102, the length of each of the third openings 1102 close to the planar region 13 is less than the length of each of the third openings 1102 away from the planar region 13. The lengths of the first openings 1101 are the same in a region of the first unidirectionally bendable region 110 other than the first transition region 111.

The second unidirectionally bendable region 120 includes a second transition region 121. The second transition region 121 is disposed in a region of the second unidirectionally bendable region 120 close to the planar region 13 in the first direction x. The second transition region 121 includes a plurality of fourth openings 1202. A length direction the plurality of fourth openings 1202 is the second direction y. A length of each of the plurality of fourth openings 1202 is less than a length of each of the plurality of second openings 1201. Among the plurality of fourth openings 1202, the length of each of the fourth openings 1202 close to the planar region 13 is less than the length of each of the fourth openings 1202 away from the planar region 13. The length of the second opening 1201 is the same in a region of the second unidirectionally bendable region 120 other than the second transition region 121.

The support bodies shown in FIGS. 8 to 14 also include the first transition region 111 and the second transition region 121 as described above. The support bodies also include the structures of the third opening 1102 and the fourth opening 1202.

The closer to the first bending axis, the greater the bending stress and the closer to the first bending axis, the greater the length of the third opening 1102, which is conducive to releasing the bending stress. The closer to the second bending axis, the greater the bending stress, and the closer to the second bending axis, the greater the length of the fourth opening 1202, which is conducive to releasing the bending stress. That is, the first transition region 111 and the second transition region 121 effectively release the stress, which is more favorable to bending and avoids fracture during bending.

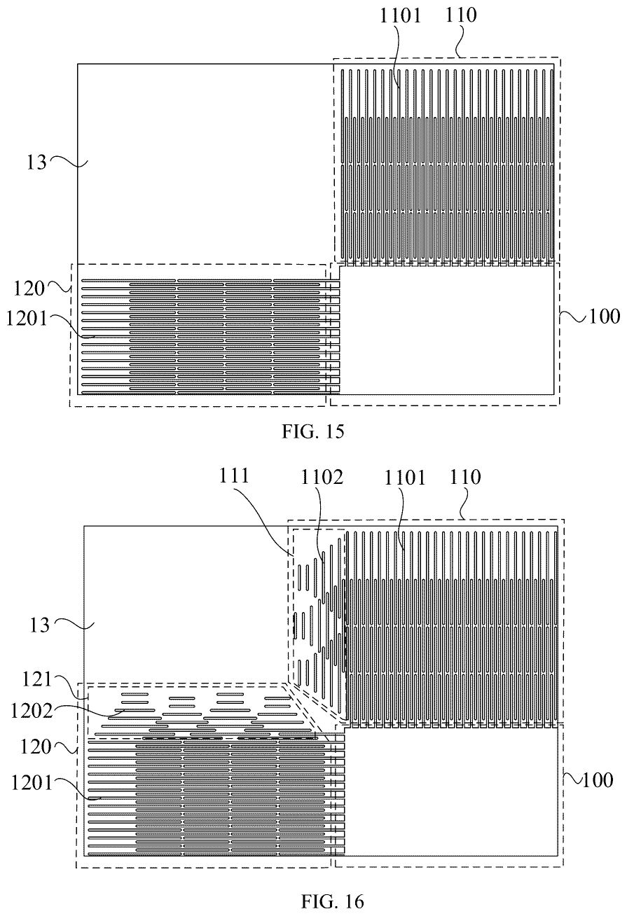

In another possible implementation, referring to FIG. 15, which is a schematic structural diagram of another support body according to some embodiments of the present disclosure, a first unidirectionally bendable region 110 does not include a first transition region 111, a second unidirectionally bendable region 120 does not include a second transition region 121, and a bidirectionally bendable region 100 has no solid structure. Similarly, the support body 10 is bidirectionally bendable.

In another possible implementation, referring to FIG. 16 which is a schematic structural diagram of another support body according to some embodiments of the present disclosure, a first unidirectionally bendable region 110 of the support body 10 includes a first transition region 111, a second unidirectionally bendable region 120 includes a second transition region 121, and a bidirectionally bendable region 100 has no solid structure. Similarly, the support body 10 is bendable.

In another possible implementation, a first unidirectionally bendable region 110 of a support body 10 includes a first transition region 111, a second unidirectionally bendable region 120 of a support body 10 includes a second transition region 121 and a bidirectionally bendable region 100 has a plurality of connection wires arranged in a first direction x. The non-solid regions (i.e., regions between the connection wires 101) in the bidirectionally bendable region 100 are filled with the elastic material. Similarly, the support body 10 is bendable. For related content of the elastic material, reference is made to the description of the elastic material in FIG. 14, which is not described herein again.

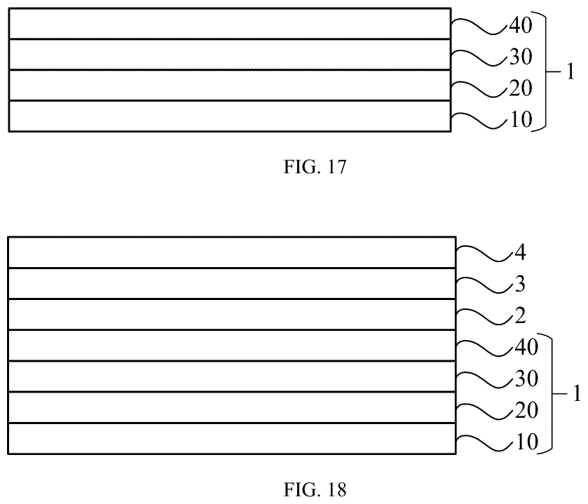

FIG. 17 is a schematic cross-sectional structural diagram of a support member 1 according to some embodiments of the present disclosure. As shown in FIG. 17, the support member 1 further includes a first bonding layer 20, a spacer layer 30, and a second bonding layer 40. The support body 10, the first bonding layer 20, the spacer layer 30, and the second bonding layer 40 are sequentially stacked.

The openings are fabricated in the support body 10 to implement the bending function in two directions. The first bonding layer 20 is connected to the support body 10 and the spacer layer 30, and the spacer layer is a whole layer structure, which facilitates other structures (e.g., a flexible display panel) on the support member 1 to remain flat. The second bonding layer 40 is connected to the support member 1 and other structures (e.g., the flexible display panel).

Exemplarily, the second bonding layer 40 is a whole layer structure and the spacer layer 30 is a whole layer structure. The first bonding layer 20 covers the planar region 13.

In one possible implementation, the first bonding layer 20 also covers at least one first unidirectionally bendable region 110 or at least one second unidirectionally bendable region 120.

Exemplarily, the thickness of the support body 10 ranges from 0.05 mm to 0.3 mm. For example, the thickness is 0.05 mm, 0.1 mm, 0.15 mm, 0.2 mm, 0.25 mm, 0.3 mm, or the like. Exemplarily, the thickness of the first bonding layer 20 ranges from 0.005 mm to 0.05 mm. For example, the thickness is 0.005 mm, 0.01 mm, 0.015 mm, 0.02 mm, 0.02 5 mm, 0.03 mm, 0.035 mm, 0.04 mm, 0.045 mm, 0.05 mm, or the like. Exemplarily, the thickness of the second bonding layer 40 ranges from 0.005 mm to 0.05 mm. For example, the thickness is 0.005 mm, 0.01 mm, 0.015 mm, 0.02 mm, 0.025 mm, 0.03 mm, 0.035 mm, 0.04 mm, 0.045 mm, 0.05 mm, or the like. Exemplarily, the thickness of the spacer layer 30 ranges from 0.005 mm to 0.2 mm. For example, the thickness is 0.005 mm, 0.01 mm, 0.03 mm, 0.05 mm, 0.08 mm, 0.1 mm, 0.12 mm, 0.015 mm, 0.2 mm, or the like.

The layers within the thickness range above neither affect the product thickness due to being too thick nor result in poor support or bonding effectiveness due to being too thin, thereby affecting the bending function of the flexible display device including the support member 1.

Exemplarily, the support body 10 is made of a metallic material such as stainless steel, a titanium alloy, an aluminum alloy, or one of a fiber-reinforced rigid composite panel such as a carbon fiber composite panel or a fiberglass composite panel. The opening pattern may be formed by etching the materials to achieve bending and have sufficient stiffness to implement the support function.

Exemplarily, the first bonding layer 20 is made of an acrylic pressure-sensitive adhesive or a silicone pressure-sensitive adhesive. The second bonding layer 40 is made of an acrylic pressure-sensitive adhesive or a silicone pressure-sensitive adhesive. These materials have adhesive properties that enable bonding.

Exemplarily, the spacer layer 30 is made of one of stainless steel, copper foil, polyimide (PI), polyethylene terephthalate (PET), an acrylic-modified foam, a polyurethane-modified foam, or silicone-modified foam. The stainless steel and the copper foil are ultra-thin materials that are bendable. All of the materials are bendable, which facilitates the bending of the support member.

Compared with the embodiments in which the bidirectionally bendable region is fully filled with the elastic material and the embodiments in which the bidirectionally bendable region has no solid structure, the embodiments of the present disclosure in which the bidirectionally bendable region 100 includes a plurality of connection wires 101 may achieve better folding reliability, smaller creases, and better impact-resistant reliability for the bidirectionally bendable region 100.

FIG. 18 is a schematic cross-sectional structural diagram of a flexible display device according to some embodiments of the present disclosure. As shown in FIG. 18, the flexible display device includes a support member 1, a flexible display panel 2, a third bonding layer 3, and a cover plate 4. The support member 1, the flexible display panel 2, the third bonding layer 3, and the cover plate 4 are sequentially stacked. The support member 1 supports the flexible display panel 2. The third bonding layer 3 is connected to the cover plate 4 and the flexible display panel 2. The cover plate 4 achieves a protective effect on the flexible display panel 2.

The support member 1 may be any one of the aforementioned support members. The type of the flexible display panel 2 is not limited in the embodiments of the present disclosure. The flexible display panel includes, but is not limited to, an organic light-emitting diode (OLED) display panel, a quantum dot light-emitting diode (QLED) display panel, or the like.

In some embodiments, the third bonding layer 3 is a whole layer structure. In some embodiments, the third bonding layer 3 is made of a pressure-sensitive adhesive or an optical adhesive. The bonding effect may be achieved by the materials, and the display function of the flexible display panel 2 is not affected.

Exemplarily, the cover 4 is made of materials such as glass or plastic. The protective effect for the flexible display panel 2 may be achieved by the materials.

Exemplarily, the flexible display device according to some embodiments of the present disclosure may be a cell phone, a tablet computer, a monitor, a laptop computer, and any other product or component that implements the display function and is foldable.

The flexible display device achieves the same effect as the aforementioned support member, which is not described herein any further.

Described above are only exemplary embodiments of the present disclosure and are not intended to limit the present disclosure, and any modifications, equivalent substitutions, improvements, or the like made within the spirit and principles of the present disclosure shall be included in the scope of protection of the present disclosure.

What is claimed is:

1. A support member, comprising:
a support body, having a planar region, at least one first bendable region, and at least one second bendable region; wherein
the at least one first bendable region and the at least one second bendable region are intersected to form at least one bidirectionally bendable region, and the support body comprises a plurality of connection wires disposed in the bidirectionally bendable region, wherein the plurality of connection wires are sawtooth-shaped and are arranged along a first direction and extend along a second direction, the first direction being an extension direction of the first bendable region and the second direction being an extension direction of the second bendable region;
a region in the first bendable region other than the bidirectionally bendable region is a first unidirectionally bendable region, wherein a first opening pattern is disposed in the first unidirectionally bendable region;
a region is the second bendable region other than the bidirectionally bendable region is a second unidirectionally bendable region, wherein a second opening pattern is disposed the second unidirectionally bendable region; and
the planar region is a region on the support body other than the at least one first bendable region and the at least one second bendable region.

2. The support member according to claim 1, wherein each of the plurality of connection wires comprises a plurality of sawtooth structures sequentially connected in the second direction, wherein each of the plurality of sawtooth structures satisfies:
$$\frac{{C}^{3}}{{A}^{3}} \times 1 {0}^{5} \leq 462$$
wherein C represents a line width of the each of the plurality of sawtooth structures, and A represents a maximum size of the each of the plurality of sawtooth structures in the first direction.

3. The support member according to claim 2, wherein a size of the each of the plurality of sawtooth structures ranges from 0.5 mm to 2 mm in the first direction; a line width of the each of the plurality of sawtooth structures ranges from 0.05 mm to 0.3 mm, and a size of an opening of the each of the plurality of sawtooth structures ranges from 0.05 mm to 1 mm.

4. The support member according to claim 1, wherein a spacing between two adjacent connection wires ranges from 0.1 mm to 2 mm.

5. The support member according to claim 1, wherein each of the plurality of connection wires comprises a plurality of sawtooth structures sequentially connected in the second direction, wherein structures of the plurality of sawtooth structures are the same, and sizes of the plurality of sawtooth structures are the same.

6. The support member according to claim 1, wherein in the first direction, a spacing of two adjacent connection wires in the bidirectionally bendable region close to a center of the bidirectionally bendable region is greater than a spacing of two adjacent connection wires away from the center of the bidirectionally bendable region.

7. The support member according to claim 1, wherein each of the plurality of connection wires comprises a plurality of sawtooth structures sequentially connected in the second direction, wherein on any one of the plurality of connection wires in the bidirectionally bendable region in the second direction, a size of a sawtooth structure close to a center of the bidirectionally bendable region in the first direction is greater than a size of a sawtooth structure away from the center of the bidirectionally bendable region in the first direction.

8. The support member according to claim 1, wherein the plurality of connection wires comprise a first connection wire and a second connection wire adjacent to each other, wherein the first connection wire and the second connection wire are symmetrically arranged about an axis of symmetry, wherein the axis of symmetry is between the first connection wire and the second connection wire and a length direction of the axis of symmetry is the second direction.

9. The support member according to claim 1, further comprising: at least one third connection wire disposed in the bidirectionally bendable region, wherein the third connection wire extends in the first direction and is connected to at least two connection wires adjacent to each other in the first direction.

10. The support member according to claim 9, wherein a plurality of openings are defined in the third connection wire, wherein the openings are in an elongated shape, a circular shape, or a diamond shape.

11. The support member according to claim 1, wherein
any one of the plurality of connection wires comprises a plurality of first portions and a plurality of second portions alternately connected;
a number of the sawtooth structures in the first portion is less than a number of the sawtooth structures in the second portion, and a size of each of the sawtooth structures in the first portion in the first direction is greater than a size of each of the sawtooth structures in the second portion in the first direction; and
the plurality of the first portions of the plurality of connection wires are arrayed along the first direction and the second direction, and the plurality of the second portions of the plurality of connection wires are arrayed along the first direction and the second direction.

12. The support member according to claim 1, wherein the support body comprises at least two bidirectionally bendable regions, wherein the at least two bidirectionally bendable regions are aligned in the first direction or in the second direction, and a spacing between the two adjacent bidirectionally bendable regions is greater than or equal to 2 mm.

13. The support member according to claim 1, wherein
the first opening pattern comprises a plurality of first openings that are arrayed, wherein a length direction of each of the plurality of first openings is the same as the first direction; and
the second opening pattern comprises a plurality of second openings that are arrayed, wherein a length direction of each of the plurality of the second openings is the same as the second direction.

14. The support member according to claim 13, wherein
the first unidirectionally bendable region comprises a first transition region, wherein the first transition region is disposed in a region of the first unidirectionally bendable region in the second direction close to the planar region; and
the first transition region comprises a plurality of third openings, wherein a length direction of each of the plurality of third openings is the first direction, a length of the each of the plurality of third openings is less than a length of the each of the plurality of first openings, and a length of a third opening in the plurality of third openings close to the planar region is less than a length of a third opening in the plurality of third openings away from the planar region.

15. The support member according to claim 13, wherein
the second unidirectionally bendable region comprises a second transition region, wherein the second transition region is disposed in a region of the second unidirectionally bendable region in the first direction close to the planar region; and
the second transition region comprises a plurality of fourth openings, wherein a length of each of the plurality of fourth openings is the second direction, a length of the each of the plurality of fourth openings is less than a length of the each of the plurality of second openings, and a length of a fourth opening in the plurality of fourth openings close to the planar region is less than a length of a fourth opening in the plurality of fourth openings away from the planar region.

16. The support member according to claim 13, wherein one or more rows of the second openings are defined between the two adjacent connection wires in the first direction.

17. The support member according to claim 1, wherein a thickness of the support body ranges from 0.05 mm to 0.3 mm;
wherein the support body is made of one of stainless steel, a titanium alloy, an aluminum alloy, a carbon fiber composite plate, and a glass fiber composite plate.

18. (canceled)

19. The support member according to claim 1, further comprising: a first bonding layer, a spacer layer, and a second bonding layer, wherein the support body, the first bonding layer, the spacer layer, and the second bonding layer are sequentially stacked.

20. The support member according to claim 19, wherein
a thickness of the first bonding layer ranges 0.005 mm to 0.05 mm;
a thickness of the second bonding layer ranges 0.005 mm to 0.05 mm; and
a thickness of the spacer layer ranges 0.005 mm to 0.2 mm;
the first bonding layer is made of an acrylic pressure-sensitive adhesive or an organosilicon pressure-sensitive adhesive; and
the second bonding layer is made of an acrylic pressure-sensitive adhesive or an organosilicon pressure-sensitive adhesive; and
the spacer layer is made of one of stainless steel, copper, polyimide, polyethylene terephthalate, an acrylic-modified foam, a polyurethane-modified foam, or a silicone-modified foam.

21-22. (canceled)

23. A flexible display device, comprising: a flexible display panel, a third bonding layer, a cover plate, and a support member;
wherein the support member, the flexible display panel, the third bonding layer, and the cover plate are sequentially stacked; and
the support member comprises:
a support body, having a planar region, at least one first bendable region, and at least one second bendable region; wherein
the at least one first bendable region and the at least one second bendable region are intersected to form at least one bidirectionally bendable region, and the support body comprises a plurality of connection wires disposed in the bidirectionally bendable region, wherein the plurality of connection wires are sawtooth-shaped and are arranged along a first direction and extend along a second direction, the first direction being an extension direction of the first bendable region and the second direction being an extension direction of the second bendable region;
a region in the first bendable region other than the bidirectionally bendable region is a first unidirectionally bendable region, wherein a first opening pattern is disposed in the first unidirectionally bendable region;
a region is the second bendable region other than the bidirectionally bendable region is a second unidirectionally bendable region, wherein a second opening pattern is disposed the second unidirectionally bendable region; and
the planar region is a region on the support body other than the at least one first bendable region and the at least one second bendable region.
